(19) United States
(12) Patent Application Publication
(10) Pub. No.: US 2026/0215226 A1
(43) Pub. Date: Jul. 23, 2026

(54) SYSTEM AND METHOD FOR OVERLAY ERROR DETECTION

(71) Applicant: Tokyo Electron Limited, Tokyo (JP)

(72) Inventors: Ivan Maleev, Fremont, CA (US); Gerrit Leusink, Albany, NY (US)

(21) Appl. No.: 19/191,855

(22) Filed: Apr. 28, 2025

Related U.S. Application Data
(60) Provisional application No. 63/747,150, filed on Jan. 20, 2025.

(51) Int. Cl. H01L 21/66; G01B 11/27; H01L 21/67

(52) U.S. Cl. CPC H10P 74/203; G01B 11/272; H10P 72/0606

(57) ABSTRACT

A method is provided for overlay error detection in a bonded wafer. The method includes receiving a bonded wafer in a bonding chamber, where the bonded wafer includes a first structure bonded to a second structure at a bonding interface. The first structure includes first overlay targets aligned with second overlay targets of the second structure at the bonding interface. The method further includes illuminating a first light beam onto a first portion of the bonded wafer for a first time duration that includes a start time. A light detector is used to detect a first temperature map of a region of the bonded wafer around the first portion illuminated by the first light beam, with the first temperature map being detected after the start time for a second time duration. Based on the first temperature map, an overlay error at the bonding interface is determined from misalignment between the first overlay targets and the second overlay targets.

### CROSS-REFERENCE TO RELATED APPLICATIONS

This application claims the benefit of U.S. Provisional Application No. 63/747,150, filed on Jan. 20, 2025, which application is hereby incorporated herein by reference.

### TECHNICAL FIELD

The present invention relates generally to a system and method for semiconductor device detection, in particular embodiments, to a system and method for overlay error detection after a wafer bonding process.

### BACKGROUND

Die-to-Wafer (D2W) and Wafer-to-Wafer (W2W) bonding processes are implemented in advanced packaging of semiconductor integrated circuits, 3D integration processes, and semiconductor development. These bonding processes can be utilized in applications such as Back-Side Power Distribution Networks (BS-PDN). The alignment between bonding entities affects the overall performance of the bonded components.

Current techniques for measuring overlay alignment errors include microscopy-based and scatterometry-based approaches. Microscopy techniques analyze images of overlay targets to determine alignment. The microscopy process involves examining shifts between designated targets on the bonding entities through image analysis. Scatterometry techniques utilize diffraction gratings as targets and measure reflectance and ellipsometric response in the specular channel. However, both microscopy-based and scatterometry-based approaches have limitations.

### SUMMARY

In accordance with a preferred embodiment of the present invention, a method for overlay error detection in a bonded wafer is provided. The method includes receiving a bonded wafer in a bonding chamber, the bonded wafer comprising a first structure bonded to a second structure at a bonding interface, wherein the first structure comprises first overlay targets aligned with second overlay targets of the second structure at the bonding interface. The method further includes illuminating a first light beam onto a first portion of the bonded wafer for a first time duration comprising a start time. The method additionally includes detecting, using a light detector, a first temperature map of a region of the bonded wafer around the first portion illuminated by the first light beam, the first temperature map being detected after the start time for a second time duration. The method also includes determining, based on the first temperature map, an overlay error at the bonding interface from misalignment between the first overlay targets and the second overlay targets.

In accordance with another embodiment of the present invention, a method for overlay error detection is provided. The method includes determining an overlay error for a calibration bonded wafer comprising a first structure bonded to a second structure. The method further includes illuminating a first light beam onto the calibration bonded wafer and imaging a temperature response to the first light beam to obtain a calibrated temperature map. The method additionally includes receiving a bonded test wafer comprising a first test structure bonded to a second test structure. The method also includes illuminating a second light beam onto the bonded test wafer and imaging a temperature response of the bonded test wafer to the second light beam to obtain a temperature map. The method further includes determining an overlay error of the bonded test wafer based on the temperature map of the bonded test wafer and the calibrated temperature map.

In accordance with yet another embodiment of the present invention, a system for overlay error detection is provided. The system includes a wafer holder disposed in a chamber, a light source and a light detector, and a controller coupled to the wafer holder, the light source and the light detector, and a memory storing instructions to be executed in the controller. The instructions when executed cause the controller to receive a bonded wafer in a bonding chamber, the bonded wafer comprising a first structure bonded to a second structure at a bonding interface, wherein the first structure comprises first overlay targets aligned with second overlay targets of the second structure at the bonding interface. The instructions further cause the controller to illuminate a first light beam onto a first portion of the bonded wafer for a first time duration comprising a start time, detect, using a light detector, a first temperature map of a region of the bonded wafer, around the first portion illuminated by the first light beam, the first temperature map being detected after a second time duration, and determine, based on the first temperature map, an overlay error at the bonding interface from misalignment between the first overlay targets and the second overlay targets.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross-sectional view of a method for detecting overlay errors in a bonded wafer, in accordance with an embodiment;

FIG. 2 illustrates a cross-sectional view of an example overlay error in a bonded wafer, in accordance with an embodiment;

FIG. 3 illustrates a cross-sectional view of another method for detecting overlay errors in a bonded wafer using refined optical configuration, in accordance with an embodiment;

FIGS. 4A-4D illustrate timing diagrams showing different operational modes of light source and detector combinations, in accordance with various embodiments;

FIG. 5A illustrates a cross-sectional view of a multi-spot method for detecting overlay errors in a bonded wafer, in accordance with an embodiment;

FIG. 5B illustrates a top view of illuminated regions in the bonded wafer of FIG. 5A, in accordance with an embodiment;

FIG. 6 illustrates a cross-sectional view of a method for detecting overlay errors using multiple optical filtering stages, in accordance with an embodiment;

FIG. 7A illustrates a cross-sectional view of a method for detecting overlay errors using a single detector with rotational scanning, in accordance with an embodiment;

FIG. 7B illustrates a top view of concentric illumination regions in the bonded wafer of FIG. 7A, in accordance with an embodiment;

FIGS. 8A-8F illustrate top-sectional views of various overlay target patterns at a bonding interface, in accordance with various embodiments;

FIGS. 9A-9E illustrate top-sectional views of additional overlay target patterns at a bonding interface, in accordance with various embodiments;

FIGS. 10A-10B illustrate system configurations for implementing overlay error detection, in accordance with various embodiments;

FIG. 11 illustrates a flowchart of a method for overlay error detection, in accordance with an embodiment; and

FIG. 12 illustrates a flowchart of a method for overlay error detection using a database, in accordance with an embodiment.

### DETAILED DESCRIPTION OF ILLUSTRATIVE EMBODIMENTS

X-ray microscopy is a conventional approach for overlay error detection during D2W or W2W bonding processes. While capable of post-bonding measurements, X-ray microscopy requires expensive equipment that is difficult to maintain and may potentially damage samples. In high-volume manufacturing environments where throughput requirements may reach 20,000 dies per wafer per hour, X-ray-based measurements become impractical due to speed limitations and operational complexity.

In various embodiments of this disclosed invention, a thermal-based measurement approach addresses these challenges by utilizing specially designed overlay targets where thermal conductivity varies as a function of target alignment. This approach involves rapidly heating or cooling the wafer or die above the bonding interface, followed by temperature measurements using remote sensing devices such as thermal cameras, photoluminescence microscopes, or single spot sensors. The temperature measurements enable calculation of thermal conductivity at the interface between overlay targets, which correlates to bonding alignment accuracy.

The thermal measurement system enables targeted scanning of specific areas with suspected misalignment, improving efficiency compared to full-surface scanning methods. This approach overcomes limitations of traditional optical overlay measurements, as the detection capability depends on thermal conductivity contrast rather than optical resolution or sensor sensitivity. The overlay targets can be designed using materials with significantly different thermal conductivities, such as insulators and metals, to enhance measurement sensitivity.

This thermal approach offers several key advantages. In various embodiments, thermal relaxation times in bonded structures may range from milliseconds to microseconds. The fast thermal response times may enable rapid, non-destructive measurements suitable for high-volume manufacturing (HVM) environments. Machine learning algorithms or artificial intelligence models can be employed to correlate temperature measurements with alignment accuracy. While X-ray measurements may be used initially for calibration and quantitative reference data, the thermal method eliminates the need for routine X-ray exposure in production environments. This results in a cost-effective, fast, and accurate measurement solution that meets manufacturing throughput requirements while maintaining measurement precision. The ability to quickly identify misaligned areas enables targeted inspection and informed decisions about subsequent processing steps, such as additional die stacking.

Embodiments provided below describe various methods, apparatuses and systems for detecting overlay errors in a bonded wafer, and in particular, to methods, apparatuses, and systems that use optical techniques to heat and monitor temperature maps across the bonded wafer to identify overlay errors. The following description describes the embodiments.

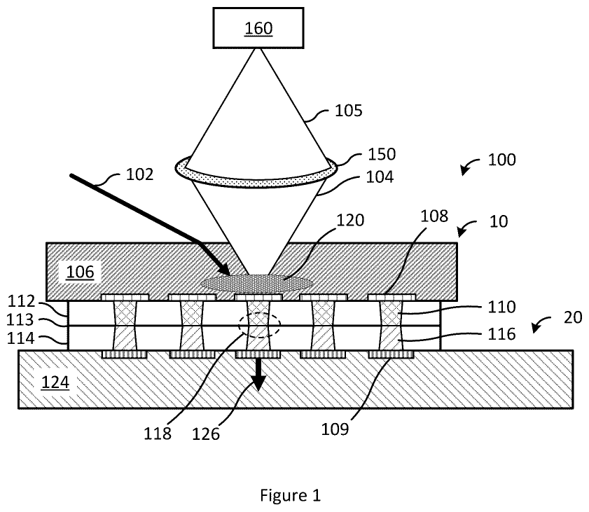

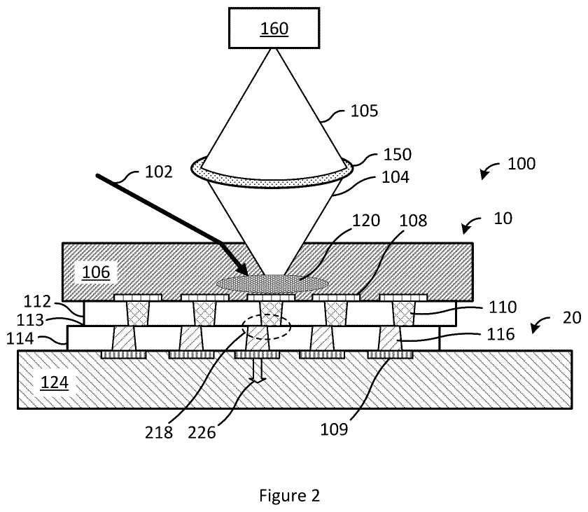

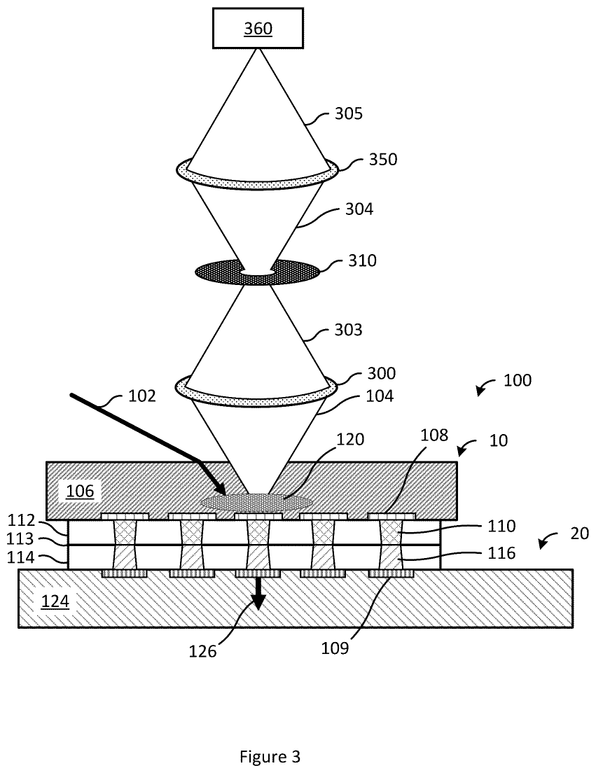

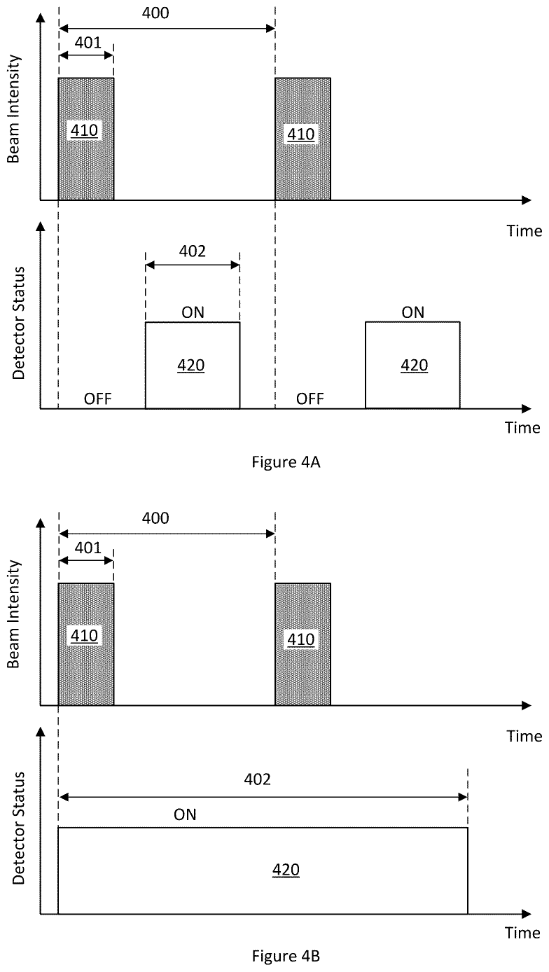

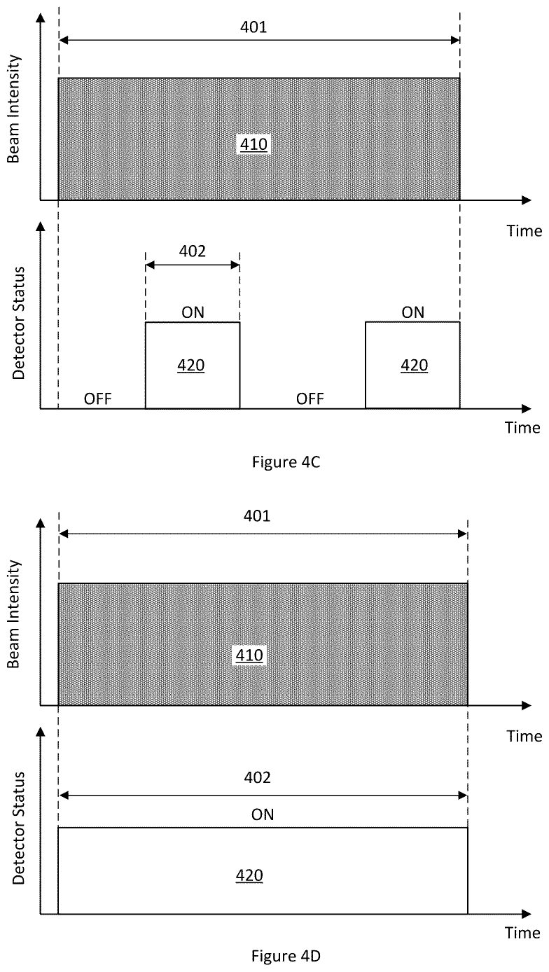

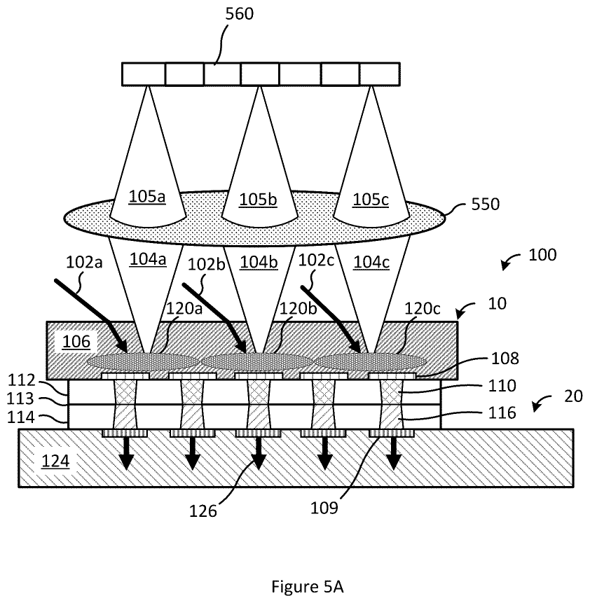

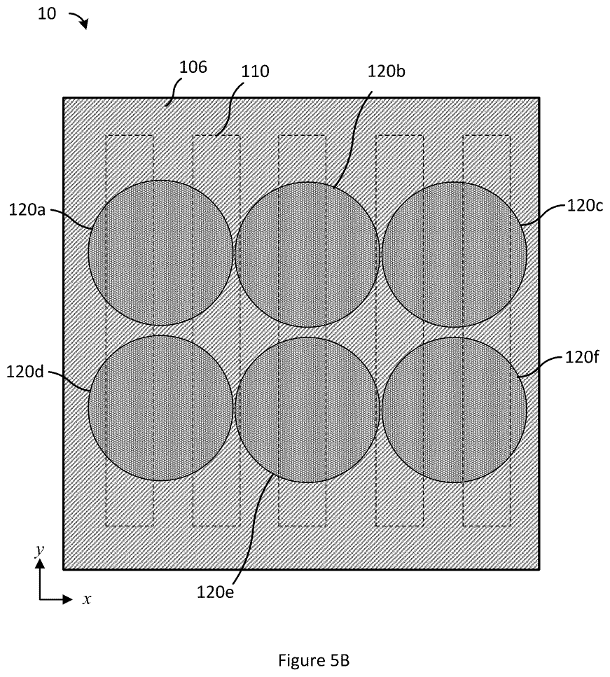

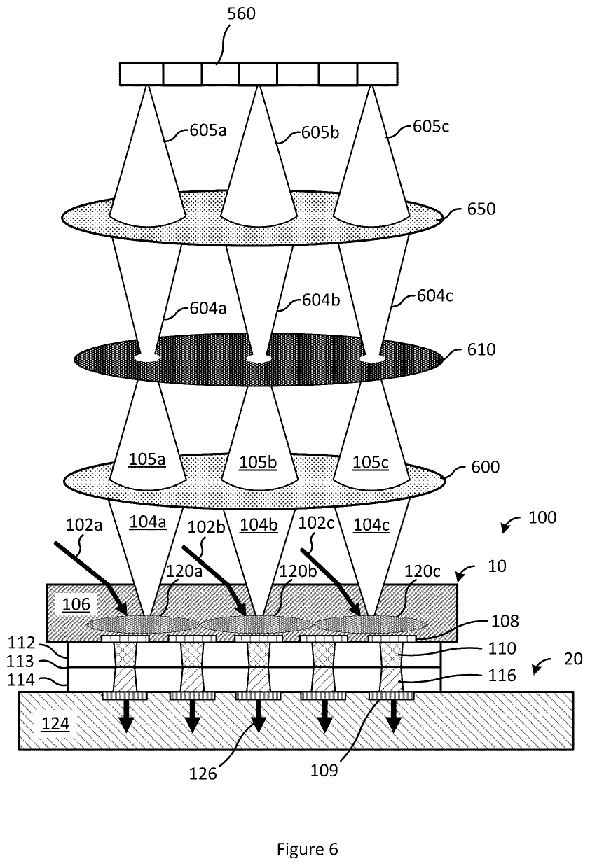

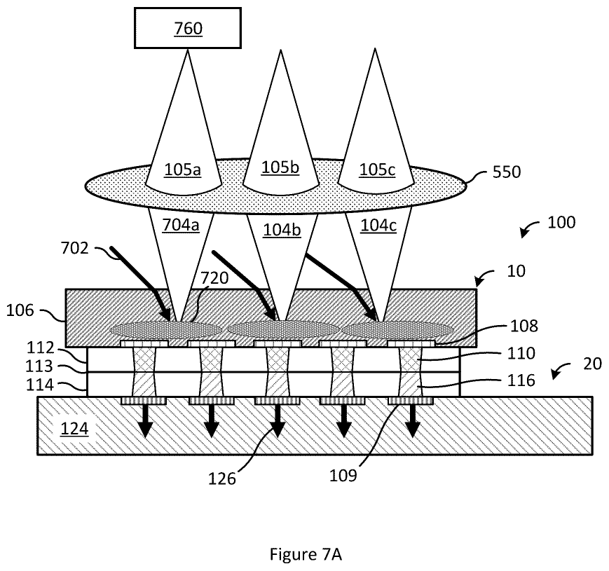

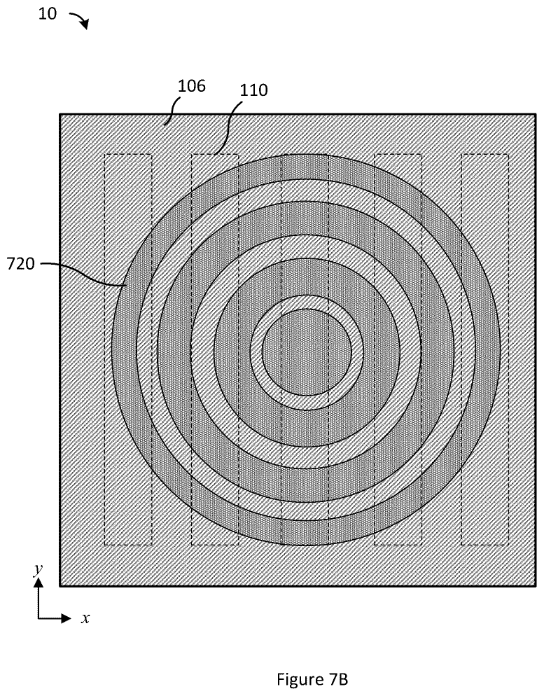

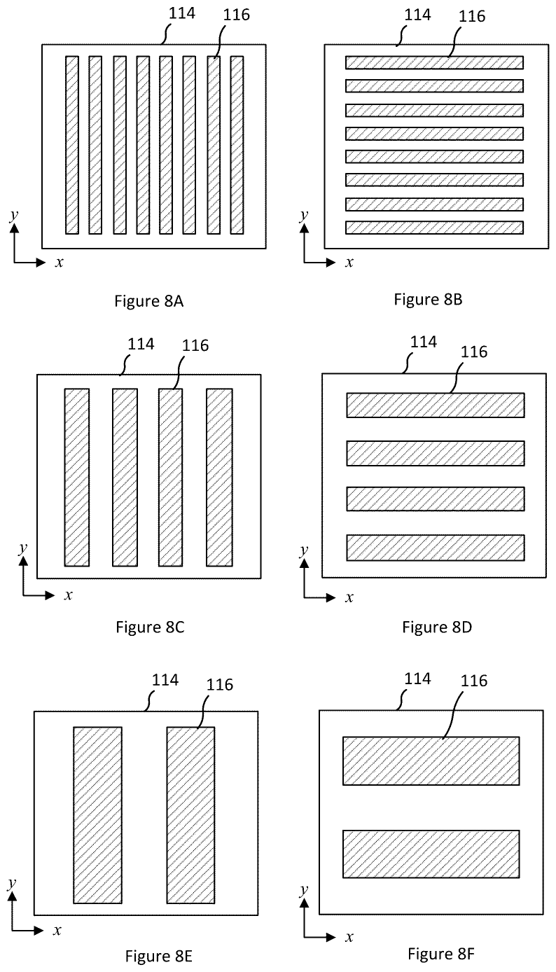

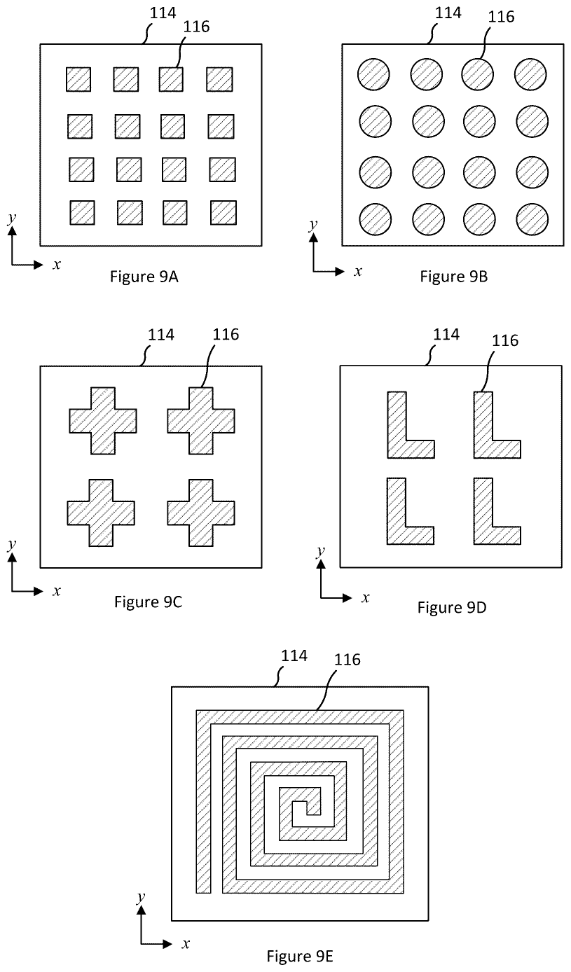

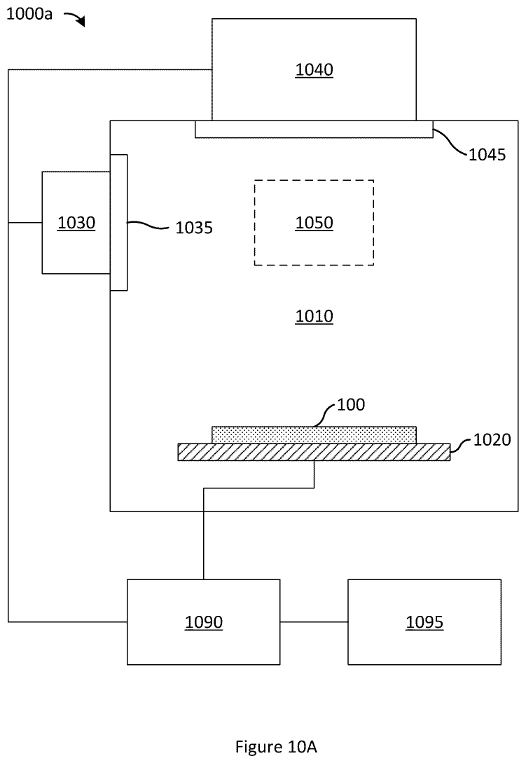

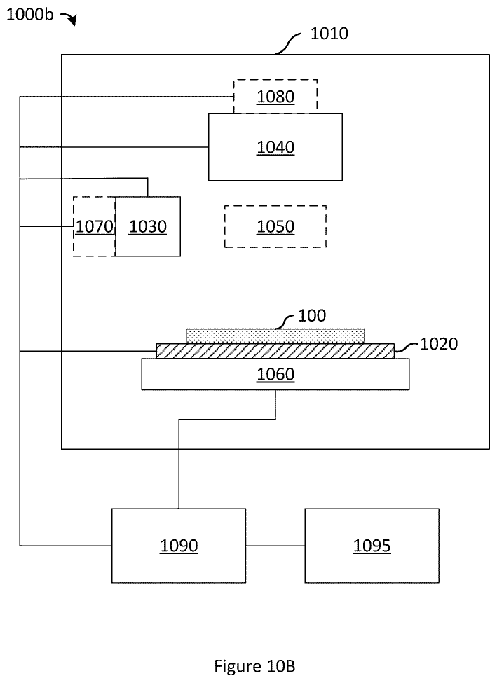

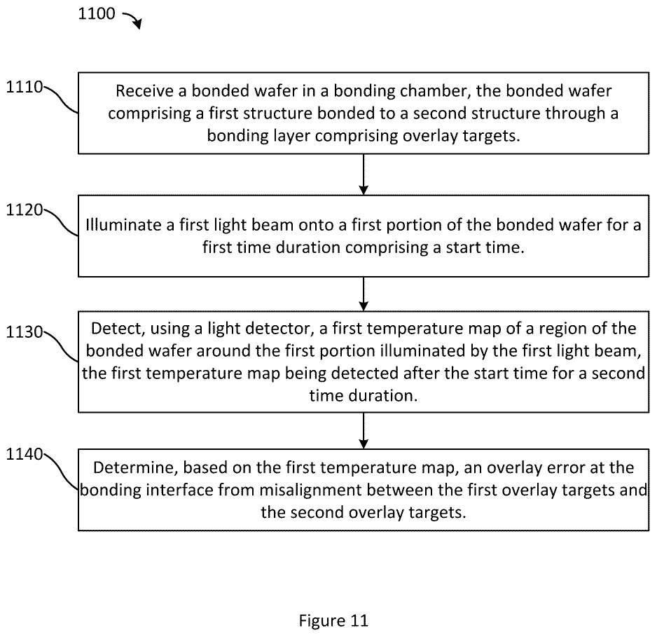

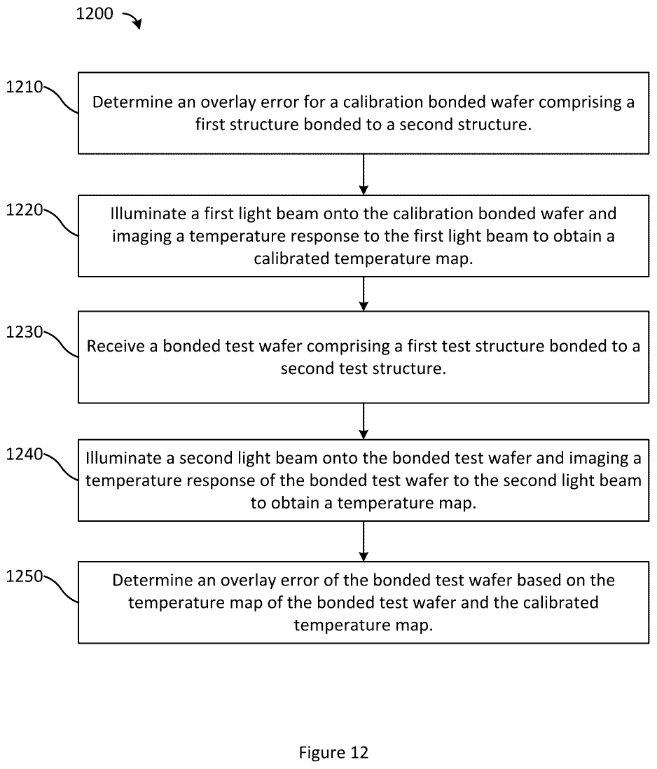

FIG. 1 describes an example method for detecting overlay errors in a bonded wafer. FIG. 2 describes one example overlay error detected using embodiment methods of this disclosure. Another embodiment method for detecting overlay errors in a bonded wafer is described using FIG. 3. FIGS. 4A-4D illustrate different operations of light source and detector over time. FIG. 5A shows yet another embodiment method for detecting overlay errors in a bonded wafer with FIG. 5B showing a top view of the illuminated structure. Another embodiment method for detecting overlay errors in a bonded wafer is described using FIG. 6. Yet another embodiment method for detecting overlay errors in a bonded wafer is described using FIG. 7A, with a top view of the illuminated structure shown in FIG. 7B. FIGS. 8A-8F show examples of overlay target patterns. FIGS. 9A-9E illustrate additional examples of overlay target patterns. Two example systems implementing the methods of detecting overlay errors in a bonded wafer are described using FIGS. 10A-10B. And the flowcharts of FIGS. 11-12 illustrate example methods of detecting overlay errors in a bonded wafer in accordance with embodiments of this disclosure.

FIG. 1 is a cross-sectional view of a bonded wafer 100 illustrating a method for detecting overlay errors in the bonded wafer 100, in accordance with an embodiment of this disclosure. The bonded wafer 100 as discussed in various embodiments may be formed through any suitable bonding method known in the art, such as direct bonding, hybrid bonding, or fusion bonding.

As illustrated in FIG. 1, the bonded wafer 100 comprises a first structure 10 bonded to a second structure 20. The first structure 10 comprises a first substrate 106 comprising a first underlying layer 108 and a first bonding layer 112. The second structure 20 comprises a second substrate 124 comprising a second underlying layer 109 and a second bonding layer 114. The first structure 10 and the second structure 20 may each comprise a wafer with a plurality of dies formed thereon or a singulated die after processing.

In the embodiment illustrated in FIG. 1, the bonded wafer 100 may be formed by bonding the first bonding layer 112 of the first structure 10 with the second bonding layer 114 of the second structure 20 through a bonding interface 113. The bonding interface 113 may be an interface layer in which the two substrates have bonded, e.g., direct or fusion bonded, in some embodiments.

The first bonding layer 112 comprises first overlay targets 110 and the second bonding layer 114 comprises second overlay targets 116. In the embodiment illustrated in FIG. 1, the bonding interface 113 comprises regions where the first bonding layer 112 directly bonds with the second bonding layer 114, and various contacts 118 formed through the bonding of the first overlay targets 110 with the second overlay targets 116. Misalignment between the first overlay targets 110 and the second overlay targets 116 indicates overlay errors in the bonded wafer 100, i.e., misalignment between the first structure 10 and the second structure 20.

Still referring to FIG. 1, the methods of detecting overlay errors in the bonded wafer 100 exposes the first structure 10 with a light beam 102 to heat or cool the first structure 10 to a desired starting temperature. In various embodiments, the first structure 10 may be exposed to the light beam 102 for a first time duration comprising a start time, which may be predetermined based on the power of the light beam 102 to achieve the desired starting temperature. Ideally, the desired starting temperature is achieved in the first structure in a short timeframe to avoid thermal conductivity to other elements of the bonded wafer 100.

In the embodiment illustrated in FIG. 1, the light beam 102 may illuminate a first portion of the first structure 10 to heat the region 120 of the first structure 10 to the desired starting temperature. The region 120 of the bonded wafer is around the first portion illuminated by the light beam 102. Additionally, the light beam 102 may be beneficially configured based on the material of the first structure 10 to heat the first structure 10 to the desired temperature within the first time duration. For example, in an embodiment where the first substrate 106 is a silicon substrate, the light beam 102 may comprise wavelengths in the near infrared range (NIR) of about 700 nm to 1000 nm. Other embodiments may utilize different wavelengths for the light beam 102 based on the materials of the first structure 10. In various embodiments, the light beam 102 may be generated from light sources comprising lasers, LED sources, halogen lamps, or arc lamps. The light sources may be configured to generate light in specific wavelength ranges suitable for absorption by the wafer materials. In an embodiment, the light beam 102 may be a focused laser beam with controlled spot size and intensity distribution.

A heat flow arrow 126 indicates the expected thermal dissipation pathway through the bonded wafer structure. In regions where the first overlay targets 110 and the second overlay targets 116 are well aligned (e.g., the contacts 118), heat is efficiently conducted from the first structure 10 to the second structure 20. In accordance with an embodiment, FIG. 2 illustrates a cross-sectional view of the bonded wafer 100 where the first overlay targets 110 and the second overlay targets 116 are misaligned by forming misaligned contacts 218. Due to the misalignment between the first overlay targets 110 and the second overlay targets 116, the heat flow may be impeded as represented by a heat flow arrow 226. Impeded heat flow may lead to potential temperature variations that may be detected through analysis of the emitted light 104a-104c. In some embodiments, the heat flow as indicated by the heat flow arrow 226 may have a smaller flow rate than the heat flow indicated by the heat flow arrow 126.

After the first structure 10 reaches the desired starting temperature, the heat will be conducted throughout the bonded wafer 100 in accordance with the thermal conductivities of proximal elements. For example, the overlay targets may conduct heat better than surrounding regions of directly bonded first bonding layer 112 with second bonding layer 114, and rapidly conduct heat to the second substrate 124 through heat flow arrows 126. As the bonded wafer 100 proceeds towards thermal equilibrium through the flow of heat from the first structure 10 throughout the rest of the bonded wafer 100, a plurality of temperature maps of the first structure 10 may be recorded over a second time duration by collecting emitted lights 104. These emitted lights may be attributed to various phenomena, such as photoluminescence, which may provide information about the temperature distribution within the region 120. Further, each temperature map of the plurality of temperature maps corresponds to the temperatures of various regions of the first structure 10 at a particular time in the second time duration. Additionally, a temperature map of the bonded wafer 100 may in one implementation be a temperature map corresponding to the first structure 10. And the temperature maps may in some implementations be the distribution of temperatures across the first structure 10 (or other layers or structures of the bonded wafer 100).

Metals in general and copper in particular have very high thermal conductivity compared to dielectrics and even semiconductor materials, such as silicon. For example, copper thermal conductivity can be approximately 400 [W/m K] at room temperature. Thermal conductivity of crystal silicon is approximately 150 [W/m K] and drops rapidly with temperature. In wafer bonding process, materials of the bonding layers (e.g., the first and the second bonding layers 112 and 114) between the overlay targets (e.g., the first and the second overlay targets 110 and 116) may comprise dielectrics such as oxides, nitrides, or carbides. For example, 5 nm FINFET metallization processes may use carbon-doped silicon oxide (CDO). The thermal conductivity of CDO is approximately 0.4 [W/m K], the thermal conductivity of regular silicon dioxide SiO₂ is approximately 1.3 [W/m K], and the thermal conductivity of SiCN(O) glass can be approximately 1.0 [W/m K]. In various embodiments, with the overlay targets comprising metals, crystal silicon, or other high thermal conductive materials, the difference in thermal conductivity between overlay targets and surrounding bonding layers may be on the order of 2-3 orders of magnitude. Therefore, in those structures, heat transfer occurs primarily through overlay targets, and the heat transfer rate is much higher through aligned overlay targets compared to some other materials like semiconductors (silicon) and typical dielectrics (e.g., SiO₂, CDO, or SiCN). In contrast, any misalignment between the overlay targets at the bonding interface 113 (e.g., the misaligned contacts 218) may reduce thermal conductivity of the features disposed in that region of the bonded wafer 100 dramatically.

The method of detecting temperature maps may then detect overlay errors in the bonded wafer 100. As an example, localized heated volumes (e.g., the region 120) of the first structure 10 disposed above well aligned overlay targets may rapidly cool through the heat flow arrows 126 (which may be detected by analyzing the plurality of temperature maps to locate regions of the first structure 10 which rapidly cooled). Further, the cooling of the localized heated volumes indicates good thermal conductivity (the heat is transferred according to expectation). And those particular localized heated volumes with good thermal conductivity may be determined to not have overlay errors.

In contrast to the localized heated volumes that rapidly cool, localized heated volumes of the first structure 10 which do not cool in accordance with the expected thermal conductivity indicate the presence of overlay errors at the bonding interface 113 (e.g., the misaligned contacts 218). In other words, heat located above a misaligned overlay targets may not dissipate nearly as rapidly as heat located above well aligned overlay targets. As a result, the determination of the presence of overlay errors identifies regions of the bonded wafer 100 that does not dissipate heat, or change temperature in accordance with expectation.

In other embodiments, a starting temperature for the heated layer may be preconfigured. As a result, potential overlay errors may be detected by analyzing a single temperature map of the bonded wafer 100 determined after the second time duration. Using the single temperature map, a change in temperature from the known starting temperature may be used to detect overlay errors in the bonded wafer 100. In other embodiments, a heat map may be determined for the heated layer, which may be an image of the heated layer from an infrared (IR) camera (or other suitable imaging devices). In those embodiments, the heat map (or image) may be compared with a reference (or control) heat map (or image) to determine differences corresponding to overlay errors in the heated layer without explicitly calculating temperatures of different regions of the heated layer. In even further embodiments, the heat map may be a temperature map, and may be used as described for the plurality of temperature maps above.

The light beam 102 is shown incident on the surface of the first structure 10. This illumination may be provided by a suitable light source, such as a laser or LED, with a wavelength chosen to be absorbed primarily within the first substrate 106 or the first underlying layer 108, or whichever layer of the bonded wafer 100 is desired to be heated. The light beam 102 may be used to heat desired layers of the bonded wafer 100 in accordance with embodiment methods for detecting overlay errors in a bonded wafer of this disclosure.

In various embodiments, the light beam 102 may be pulsed light beam of suitable wavelength with penetration or absorption depth equal to a layer thickness desired to be heated may be used. In particular, the method which uses illumination light intends for the light beam 102 to be completely absorbed in the targeted layer of the bonded wafer 100 above the overlay targets (except the light reflected from top sample surface). For example, when the bonded wafer 100 is a D2W structure, and where a 50 μm thick silicon die is bonded to the wafer substrate, the light beam 102 may use visible or near-infrared wavelengths such that the absorption depth for the wavelength is comparable to the die thickness. In this example, the 50 μm thick die silicon substrate may be heated with no energy penetrating into the second structure 20 below, and the heat transfer process through the bonding interface 113 with overlay targets (or first overlay targets 110 and second overlay targets 116 forming the contacts 118) can be facilitated in the most advantageous/efficient way.

The method illustrated in FIG. 1 may use a light detector 160 to collect the emitted light 104 to determine the temperature maps of the bonded wafer 100. In various embodiments, relative movement between the light detector 160 and the bonded wafer 100 enables comprehensive surface scanning for alignment verification. The scanning may be achieved through multiple approaches. In one embodiment, the light detector may move across the surface of the bonded wafer 100 in a predetermined pattern while the wafer remains stationary, enabling sequential detection of thermal responses from different regions. In an alternative embodiment, the bonded wafer 100 may be mounted on a rotating stage, allowing the wafer to spin while the detector remains fixed. In various embodiments, the scanning motion may combine both linear and rotational movements to optimize coverage and measurement efficiency. The scanning speed, pattern, and coverage area may be adjusted based on specific measurement requirements and throughput needs. The scanning motion may be synchronized with beam illumination and detector activation timing to ensure proper coverage and data collection across all regions of interest.

In various embodiments, a type of the light detector 160 used depends on the type of emitted light 104 employed in the method. In various embodiments, the emitted lights 104 may be black body radiation or conventional light emission through thermal radiation, and the light detector may be an infrared camera configured to measure the temperature using the black body radiation. However, in those embodiments, there may be difficulty in localizing the volume that corresponds to the measured temperature. In other embodiments, a bandgap photoluminescence approach may be used, which may use a light detector to measure photoluminescence photons emanated from the heated region 120. In those embodiments, a light source (which may be the same light source used to generate the light beam 102) may be used to emit an excitation light preconfigured to excite the heated region 120. The excited heater region may radiate the emitted lights 104 as photoluminescence photons. In bandgap photoluminescence embodiments, the light detector may be a line or area multi-pixel detector.

In various embodiments, the emitted light 104 may be collimated and directed using imaging optics 150 for collection to determine the plurality of temperature maps of the bonded wafer 100. In some embodiments, the imaging optics 150 may produce focused lights 105 from the emitted lights 104. The imaging optics 150 may be designed to efficiently collect the emitted lights 104 from the bonded wafer 100 and may comprise a system of lenses, or mirrors, or other suitable conventional optical equipment known in the art.

The light detector 160 may be positioned to receive the focused lights 105 to detect a first temperature map of the bonded wafer 100 after the second time duration. In various embodiments, the light detector 160 may be a high-sensitivity, single-pixel or multi-pixel sensor capable of measuring the intensity and potentially the spectral characteristics of the incoming light, providing data that can be correlated with the local thermal properties of the bonded wafer 100. In various embodiments, the light detector 160 may be a single pixel photodiode, an avalanche photodiode (APD), a photomultiplier tube (PMT), or another single-pixel detector, or multi-pixel detector.

In alternative embodiments, the localized temperature distribution and resulting stress or thermal expansion may be measured using photoelastic or phase shift deflectometry techniques.

Still referring to FIG. 1, the first structure 10 and the second structure 20 may be any conventional semiconductor structures suitable for forming the bonded wafer 100. For example, the first structure 10 may be a die bonded to the second structure 20 which is a wafer, which may be a carrier wafer or a semiconductor wafer with a plurality of dies formed thereon. In another embodiment, the first structure 10 may be a first semiconductor wafer bonded to the second structure 20 which is a second semiconductor wafer.

The first substrate 106 may be any suitable substrate for which forming the first structure 10 is desired. Specifically, the first substrate 106 may be any suitable substrate for which forming the bonded wafer 100 and using the method of detecting overlay errors in the bonded wafer 100 may be advantageous. In various embodiments, the first substrate 106 is a wafer and is a silicon wafer in one embodiment. In other embodiments, the first substrate 106 is a die and is a silicon die in one embodiment. More possible substrates may be flat panel displays, photolithography masks, and others. Although many substrates are circular, there is no requirement that the first substrate 106 be circular or even substantially circular. For example, the first substrate 106 may be circular, square, rectangular, or any other desired shape such as irregular shapes. The second substrate 124 may be as described above for the first substrate 106, but suitable for forming the second structure 20.

The first bonding layer 112 may be any suitable material for forming the first structure 10. For example, the first bonding layer 112 may be a dielectric layer of SiO₂, or a layer stack comprising alternating dielectric layers of SiO₂ and SiN in various embodiments. Other typical dielectrics which may be used for the first bonding layer 112 comprise CDO or SiCN. Similarly, the second bonding layer 114 may be as described for the first bonding layer 112, and may also be a dielectric layer suitable for forming the second structure 20.

The first underlying layer 108 may be any suitable material or comprise electrical devices for which interconnects formed through bonding the first overlay targets 110 with the second overlay targets 116 is desired. In other embodiments, the first underlying layer 108 may comprise a variety of electrical components formed before depositing the first bonding layer 112 over the first underlying layer 108. For example, the first underlying layer 108 may be an underlying integrated circuit (IC) formed through conventional methods, and vias which may become the first overlay targets 110 may be formed through conventional methods to form interconnects between the first structure 10 and the second structure 20. In various embodiments, the second structure 20 may comprise the second underlying layer 109 which may be as described for the first underlying layer 108 of the first structure 10.

The first overlay targets 110 and the second overlay targets 116 may be any suitable material for forming the interconnects between the first structure 10 and the second structure 20, and for bonding the first structure 10 and the second structure 20 to form the bonded wafer 100. For example, the first overlay targets 110 and the second overlay targets 116 may be metal contacts of copper, tungsten, or any other conventional and/or suitable metal known in the art.

The bonding interface 113 may be formed through conventional bonding processes known in the art for forming the bonded wafer 100. As illustrated in FIG. 1, the bonding interface 113 comprises the regions of the first bonding layer 112 and the second bonding layer 114 bonded together, the contacts 118 (which facilitate electrical and thermal connections between the first bonding layer 112 and the second bonding layer 114). The bonded wafer 100 may be bonded by the bonding interface 113 through any conventional bonding process known in the art, such as through adhesive bonding, anodic wafer bonding, eutectic wafer bonding, fusion wafer bonding, glass frit wafer bonding, metal diffusion wafer bonding, hybrid wafer bonding, or solid-liquid inter-diffusion (SLID) wafer bonding.

While FIG. 1 illustrates using the light beam 102 for localized heating, various additional methods of controlling wafer temperature may be employed in conjunction with or as alternatives to the optical heating. In one or more embodiments, a wafer holder may comprise a temperature-controlled chuck for overall wafer temperature control. In various embodiments, localized temperature control may be achieved through directed streams of heated or cooled gases, or through controlled delivery of droplets or molecular clusters onto the bonded wafer top surface. These thermal control methods may include cryogenic droplets for localized cooling or heated gas streams for localized heating. The temperature control method may be selected based on specific material properties, measurement requirements, or processing constraints while maintaining the ability to create and detect localized thermal gradients for alignment verification.

The method illustrated in FIG. 1 and embodiment methods described throughout this disclosure allow for non-destructive evaluation of the bonded wafer structure, where variations in the intensity or spectral characteristics of the emitted light 104 can be correlated with the alignment between the first overlay targets 110 and the second overlay targets 116 within the bonding interface 113 or the contacts 118.

By scanning the light beam 102 across the wafer surface and analyzing the resulting signals at the light detector 160, this system can create a detailed map of thermal properties across the bonded wafer structure. This approach enables non-destructive, high-resolution evaluation of bonded interfaces and can identify overlay errors that may impact the performance or reliability of the bonded wafer structure. This approach may be referred to as a spot scan approach that reduces overall power requirements since only a small area is illuminated at a time. The focused spot allows for high spatial resolution by concentrating energy in a small area, enabling detection of localized alignment variations.

FIG. 3 is a cross-sectional view of the bonded wafer 100 illustrating a method for detecting overlay errors in the bonded wafer 100, in accordance with an embodiment of this disclosure. Similarly labeled elements may be as previously described. Further, FIG. 3 illustrates a refined optical configuration for analyzing the thermal properties of a bonded wafer 100.

The system begins with the light beam 102 as described with reference to FIG. 1, which is directed onto the surface of the bonded wafer 100. This illumination may serve to excite the sample and induce thermal changes in the structure over the region 120 exposed to the light beam 102. In an embodiment, the light beam 102 may have a wavelength of 785 nm. In other embodiments, the light beam 102 may comprise single wavelengths from or spectrums of wavelengths from the NIR spectrum (between about 700 nm to about 1000 nm). In response to the heating through the light beam 102, the illuminated region may emit lights 104 through two mechanisms. In one mechanism, an excitation light comprising wavelengths between about 1000 nm to about 1200 nm may cause bandgap photoluminescence photons to be emitted from the region 120. In another mechanism, the heated region may emit blackbody radiation with wavelengths characteristic of the local temperature. Both the photoluminescence and blackbody radiation components of the emitted lights 104 carry information about the local thermal properties of the illuminated region. The specific detection wavelength ranges may be selected based on the material properties and temperature ranges of interest for overlay error detection.

In various embodiments, the emitted lights 104 may be collected and focused by the first relay optics 300, resulting in first focused lights 303. This initial focusing step helps to collimate and direct the emitted lights for further processing. The first focused lights 303 may pass through a spatial filter 310, which selectively transmits lights from specific layers of interest within the bonded wafer structure. This filtering process may produce filtered lights 304, which contain information primarily from the desired depth or layer within the sample, such as the region immediately above the overlay targets.

The filtered lights 304 then encounter second relay optics 350, which further focus the lights into second focused lights 305. This additional focusing step helps to optimize the lights collection efficiency and spatial resolution of the system. And finally, the second focused lights 305 may be directed onto a light detector 360. This detector may be a high-sensitivity, single-pixel or multi-pixel sensor capable of measuring the intensity and potentially the spectral characteristics of the incoming light. In various embodiments, the light detector 360 may be a single pixel photodiode, an avalanche photodiode (APD), a photomultiplier tube (PMT), or multi-pixel detector.

The incorporation of the spatial filter 310 and multiple relay optics (300 and 350) allows for precise control over which regions of the sample contribute to the detected signal. This configuration may significantly enhance the system's ability to isolate information from specific layers or interfaces within the bonded wafer structure, potentially improving the detection sensitivity for overlay errors.

In various embodiments, the light beam 102 applied to the bonded wafer 100 may be supplied either continuously or in a pulsed mode to illuminate the first portion of the bonded wafer. FIGS. 4A-4D illustrate different timing configurations between beam illumination (e.g., the light beam 102) and detector (e.g., the light detectors 160 and 360) operation for temperature map detection.

In FIG. 4A, a pulsed beam configuration is shown where the beam intensity 410 operates in periodic pulses at a predetermined frequency for a first time duration 401 comprising a start time within a measurement cycle 400. The light detector status 420 may synchronize after the start time to activate and deactivate in accordance with the predetermined frequency to detect the first temperature map of the bonded wafer 100. In some embodiments, the light detector status 420 may activate for a second time duration 402 that follows the first time duration 401, enabling temperature map detection during the cooling period when the beam is off. This configuration minimizes interference from the illumination source during detection.

In some embodiments, the second time duration 402 may follow the first time duration 401 after a predetermined delay interval, allowing the temperature distribution to stabilize before measurement. In alternative embodiments, the second time duration 402 may begin immediately upon completion of the first time duration 401 to capture initial thermal response characteristics.

In various embodiments, the timing between the first time duration 401 and second time duration 402 can be adjusted based on thermal properties of the bonded wafer materials. For example, materials with high thermal conductivity may benefit from immediate detection, while materials with slower thermal response may require a stabilization period between illumination and detection. In an embodiment, the delay interval, if used, can range from microseconds to milliseconds depending on the specific overlay target design and material composition.

FIG. 4B demonstrates another pulsed beam arrangement where the beam intensity 410 maintains the same pulsed pattern with first time duration 401, but the detector status 420 remains continuously on, including periods overlapping with and extending beyond the illumination pulses. This approach captures thermal responses during both heating and cooling phases to generate comprehensive temperature maps.

In FIG. 4C, the beam intensity 410 provides continuous illumination over an extended first time duration 401, while the detector status 420 activates periodically for the second time durations 402. The second time duration 402 may partially overlap with the continuous illumination period, allowing detection of thermal responses under steady-state heating conditions.

FIG. 4D shows continuous beam operation where both beam intensity 410 and detector status 420 remain active throughout their respective durations 401 and 402. The continuous detection enables uninterrupted monitoring of thermal responses for temperature mapping under constant illumination.

In various embodiments, the continuous beam operations (FIGS. 4C, 4D) may apply lower energy over longer durations to reduce peak power requirements and thermal stress on the wafer while enabling the use of conventional IR sensors without requiring nanosecond-scale response times. The continuous beam operations may provide stable and reliable measurements, particularly in high-volume manufacturing environments where measurement consistency is crucial. The continuous beam operations may also simplify the timing requirements for detector operation and data acquisition, potentially reducing system complexity and cost while maintaining measurement sensitivity.

In various embodiments, the illumination and detection patterns described above may be combined or modified to optimize measurement sensitivity and throughput. For example, multiple pulsed beams may be employed with different pulse durations and intervals. The detector activation timing may alternate between continuous and periodic sampling within a single measurement sequence. In some embodiments, a first measurement may utilize pulsed illumination with synchronized detection as shown in FIG. 4A, followed by continuous illumination with periodic sampling as shown in FIG. 4C to capture different thermal response characteristics. The beam intensity may be varied during the first time duration 401, such as ramping up or down, or applying multiple intensity levels. Similarly, the detector status 420 may incorporate varying sampling frequencies or durations during the second time duration 402. In one or more embodiments, the measurement cycle 400 may include combinations of heating and cooling periods with corresponding detection patterns optimized for specific overlay target designs or material compositions. These various combinations of illumination and detection timing patterns enable flexible measurement strategies adaptable to different bonded wafer configurations and alignment verification requirements.

FIG. 5A is a cross-sectional view of the bonded wafer 100 illustrating another method for detecting overlay errors in the bonded wafer 100, in accordance with an embodiment of this disclosure. Additionally, FIG. 5A demonstrates a multi-spot (or referred to as flood imaging) illumination and detection scheme, which may be capable of exposing and collecting light over the entire bonded wafer 100 simultaneously. Similarly labeled elements may be as previously described.

In FIG. 5A, light beams 102a-c may be illuminated on regions 120a-c of the bonded wafer 100 which may generate emitted lights 104a-c. In some embodiments, the emitted lights 104a-c may be photoluminescence photons through bandgap photoluminescence of the bonded wafer 100. The absorption depth of the excitation light used to cause the emission of photoluminescence photons through bandgap photoluminescence may be controlled through the selection of wavelength used. As a result, the light beams may target specific layers of the bonded wafer 100 to cause photoluminescence photons to be emitted exclusively from the targeted regions, which may provide higher resolution in temperature measurements. In alternative embodiments, the emitted lights 104a-c may be blackbody radiations as described with reference with FIG. 1.

Afterwards, the emitted lights 104a-c may be collimated and directed using imaging optics 550 for collection to determine the plurality of temperature maps of the bonded wafer 100. And the imaging optics 550 may produce focused lights 105a-c from the emitted lights 104a-c, respectively.

As illustrated in FIG. 5A, a light detector 560 may be used to collect focused lights 105a-c to determine a plurality of temperatures for each portion of the bonded wafer 100 over a second time duration. In various embodiments, the light detector 560 may be a line multi-pixel detector, or an area multi-pixel detector. In certain embodiments, the light detector 560 may spatially resolve and register light of a spectrum comprising wavelengths between about 1000 nm and 1200 nm and targeted for the detection of the photoluminescence photons. The imaging optics 550 are designed to efficiently collect the emitted lights 104a-c from the bonded wafer 100 and may comprise a system of lenses, or mirrors, or other suitable conventional optical equipment known in the art.

The light detector 560 may be positioned to receive the collected light from the imaging optics 550. This detector may be a high-sensitivity, multi-pixel sensor capable of resolving spatial and spectral information from the emitted light. The detector 560 can capture the intensity and potentially the spectral characteristics of the light emitted, providing data that can be correlated with the local thermal properties of the bonded wafer 100.

This multi-spot configuration allows for simultaneous probing of multiple areas on the bonded wafer 100 surface, enabling efficient spatial mapping of thermal properties. By analyzing the differences in the emitted light characteristics from various spots, it becomes possible to identify and locate misalignments between overlay targets thus the overlay errors of the bonded wafer. This approach allows for rapid, high-resolution imaging of wafer surfaces to detect overlay errors that may impact the performance and reliability of the bonded structures.

FIG. 5B illustrates a top view of the first structure 10 showing illuminated regions 120a-f by the light beams, in accordance with an embodiment. In various embodiments, the first substrate 106 may comprise multiple illumination regions 120a-120f arranged in a grid pattern from the top view. The x and y coordinates indicate the spatial orientation of the measurement pattern relative to the wafer surface. While FIG. 5B shows six circular regions arranged in a 2×3 array configuration, in various embodiments, the number and arrangement of measurement regions may extend across the entire surface of first substrate 106.

In one or more embodiments, each region 120a-120f may represent an area where a light beam is directed for thermal measurements. The emitted light from these regions may be detected to generate temperature maps indicating thermal response characteristics at each location. By measuring multiple regions across the wafer surface, a comprehensive temperature map can be generated to detect possible overlay errors between the bonded structures (e.g., the first structure 10 and the second structure 20).

In various embodiments, the arrangement and number of illumination regions 120 may be configured based on factors such as wafer size, overlay target pattern, overlay target density, and required measurement resolution. The systematic coverage of multiple measurement points across the wafer surface enables thorough alignment verification between the bonded structures.

FIG. 6 is a cross-sectional view of the bonded wafer 100 illustrating a multi-spot thermal measurement method incorporating multiple stages of optical elements, in accordance with an embodiment. The method builds upon the previously described configuration in FIG. 5A by implementing additional optical filtering and focusing capabilities for improved measurement sensitivity.

In various embodiments, multiple light beams 102a-c illuminate regions 120a-c in the first substrate 106 of the bonded wafer 100. In some embodiments, the illuminated regions may generate emitted lights 104a-c comprising blackbody radiation resulting from local heating. In alternative embodiments, the emitted light 104a-c may comprise bandgap photoluminescence with wavelengths between about 1000 nm to 1200 nm. The type of emitted light detected may depend on the material properties and temperature range of the measurement regions. In one or more embodiments, both blackbody radiation and photoluminescence may be detected to provide complementary temperature information.

In one or more embodiments, the emitted lights 104a-c may be collimated and directed using first relay optics 600 to produce focused lights 105a-c, respectively. Afterwards, the focused lights 105a-c may be collected by a spatial filter 610 which may selectively transmit light from specific layers of interest within the bonded wafer structure. The filtered lights 604a-c may be collimated and directed using second relay optics 650 to produce focused filtered lights 605a-c. The focused filtered lights 605a-c may be detected by the light detector 560.

Through the incorporating multiple stages of optical elements into simultaneous multi-spot illumination and detection, this configuration achieves both high throughput and high measurement sensitivity. The filtered and optimized optical paths for multiple measurement spots 120a-c enable parallel processing of thermal response data across different wafer regions while maintaining the ability to isolate signals from critical bonding interface layers. This combination of spatial filtering, optimized light collection, and parallel multi-spot measurement provides advantages in measurement speed, sensitivity, and reliability compared to single-spot scanning or unfiltered detection approaches.

FIGS. 7A and 7B illustrate an alternative embodiment utilizing a light detector 760 to detect emitted lights from concentric illustrated regions, in accordance with one embodiment. FIG. 7A shows a cross-sectional view of the bonded wafer 100 where multiple light beams 702 may illuminate regions 720 in the first substrate 106. Emitted lights 704a-c from the illuminated regions 720 may be collected and focused through the imaging optics 550, producing focused lights 105a-c directed toward the light detector 760. In various embodiments, the light detector 760 may be a single pixel photodiode, an avalanche photodiode (APD), a photomultiplier tube (PMT), or multi-pixel detector.

In various embodiments, either the bonded wafer 100 may be rotated or the light detector 760 may be moved to sequentially detect the focused lights 105a-c from different measurement regions. The imaging optics 550 maintains spatial resolution and collection efficiency while enabling sequential detection of multiple measurement spots using the single detector 760.

FIG. 7B illustrates a top view of the illumination pattern, showing regions 720 arranged in a concentric circular pattern in the first substrate 106, in accordance with an embodiment. This concentric arrangement enables systematic coverage of the wafer surface through rotation. The regions 720 may be positioned to align with underlying overlay targets 110 at the bonding interface. In various embodiments, the concentric pattern may extend to cover larger areas of the first structure 10, allowing comprehensive alignment verification across the bonded wafer surface.

In various embodiments, the overlay error detection results obtained from the methods described in FIGS. 1 to 7B may enable informed decisions for subsequent processing steps. When significant misalignment is detected in specific regions of the bonded wafer 100, these areas may be flagged to prevent additional die stacking operations. For example, in applications requiring multiple die stacks of up to 16 layers, regions showing overlay errors above acceptable thresholds may be excluded from further stacking processes to prevent yield loss. Moreover, the thermal measurement data may provide a wafer map identifying both well-aligned regions suitable for continued processing and problematic areas requiring attention. This information enables selective processing where measurement efforts may be concentrated on regions of interest or concern. In time-critical applications, spot checks may be performed on specific target locations rather than full wafer scanning. The system thus provides flexibility to balance between comprehensive inspection and rapid throughput based on process requirements and prior knowledge of wafer conditions. Additionally, the overlay error data may be fed back to bonding process control systems to prevent similar alignment issues in subsequent wafers.

FIGS. 8A-8F illustrate various configurations of overlay target arrangements viewed from the top of the bonding interface 113 of the bonded wafer 100, in accordance with various embodiments. In these views, the second bonding layer 114 comprises the second overlay targets 116 which are designed to align with corresponding first overlay targets 110 (not visible in this top view) at the bonding interface 113. When the patterns of two overlay targets (110 and 116) are fully aligned with each other, the bonded wafer may exhibit maximum thermal conductivity across the bonding interface. In various embodiments, the first overlay targets 110 and the second overlay targets 116 comprise matching patterns of parallel lines or stripes to enable precise alignment verification.

FIG. 8A illustrates a high-density pattern at the bonding interface 113 where the second overlay targets 116 may comprise closely-spaced parallel stripes within the second bonding layer 114. The pattern features multiple narrow stripes along y-direction with minimal spacing between them, arranged in a fine-pitched configuration. This dense pattern may enable highly sensitive detection of small overlay errors, as even slight misalignment between the second overlay targets 116 and corresponding first overlay targets 110 may significantly affect thermal conductivity. In one embodiment using a 25 nm pitch process, the stripes may be fabricated with 10 nm width, where a 1 nm misalignment between overlay targets may result in approximately 10% reduction in thermal conductivity across the bonding interface. FIG. 8B shows a contrasting arrangement where the stripes are oriented horizontally (along x-direction) to provide sensitivity to vertical (y-direction) overlay targets misalignment.

FIG. 8C presents a different pattern of stripes with lower density than that in FIG. 8A. In some embodiments, it may be four widely-spaced vertical stripes along y-direction. The increased spacing between stripes may provide distinct thermal conductivity regions with clear boundaries. This configuration may be particularly suitable for situations requiring lower pattern density or larger alignment tolerances while maintaining sensitivity to x-direction misalignment. FIG. 8D maintains the horizontal orientation of FIG. 8B, similar to the spacing concept of FIG. 8C. This pattern creates distinct thermal conductivity zones with horizontal sensitivity to vertical (y-direction) misalignment.

FIG. 8E represents a pattern of stripes with further lower density compared to FIG. 8C, reducing to just two large vertical rectangular elements in accordance with one embodiment. The pattern in FIG. 8E may be suitable for coarse alignment verification or situations where simple, robust patterns are preferred. The larger features may provide clear thermal signatures while sacrificing fine resolution capability. FIG. 8F shows two large horizontal rectangular elements along x-direction, contrasting with the vertical orientation in FIG. 8E. This basic pattern maintains the capability to detect y-direction misalignment while using maximum feature sizes and spacing.

In various embodiments, while FIGS. 8A-8F illustrate specific examples of overlay target configurations, the patterns may be implemented with numerous variations. The number of stripes in each pattern may be increased or decreased from the shown examples, and spacing between stripes may be adjusted based on specific alignment requirements. The width of individual stripes may vary within a single pattern, combining narrow elements for high sensitivity with wider elements for larger overlay error detection. In one or more embodiments, the patterns may integrate both horizontal and vertical elements in a single pattern design to enable simultaneous x- and y-direction measurements. The aspect ratios of the rectangular elements may be modified, and the patterns may incorporate varying pitch-to-width ratios across different regions of the bonding layer. Additionally, the overlay targets may combine features from different pattern types. For example, incorporating both fine-pitched regions similar to FIG. 8A and widely-spaced elements as shown in FIG. 8C within a single bonding layer. This flexibility in pattern design enables optimization for specific applications while maintaining the fundamental thermal conductivity-based measurement approach.

FIGS. 9A-9E illustrate different configurations of overlay target arrangements viewed from the top of the bonding interface 113 of the bonded wafer 100, in accordance with various embodiments. FIG. 9A illustrates an array configuration at the bonding interface 113 where the second overlay targets 116 may comprise a 4×4 grid of square elements within the second bonding layer 114. This regular grid pattern may enable detection of misalignment in both x and y directions simultaneously. The uniform distribution of square elements provides multiple measurement points across the bonding layer.

FIG. 9B shows a similar grid arrangement but uses circular elements instead of squares. The circular pattern may provide advantages in thermal distribution characteristics due to the absence of corners. This configuration maintains the capability for bi-directional alignment verification while potentially offering different thermal conductivity profiles at the bonding interface.

FIG. 9C illustrates a more complex pattern using cross-shaped elements. Four cross-shaped overlay targets 116 may be arranged symmetrically within the second bonding layer 114. The extended arms of the crosses provide increased sensitivity to misalignment in multiple directions, while the symmetrical arrangement enables balanced thermal measurements.

FIG. 9D features L-shaped elements arranged in a rotational pattern. This configuration may provide distinct angular features that can be particularly sensitive to rotational misalignment in addition to x-y displacement. The L-shaped patterns may create unique thermal conductivity signatures depending on the alignment between overlay targets.

FIG. 9E presents a spiral pattern design where the second overlay targets 116 form a continuous square spiral within layer 114. This progressive pattern may provide a continuous gradient of thermal conductivity variation and may be particularly effective at detecting both translational and rotational misalignment through its varying geometry from center to edge.

In various embodiments, the patterns illustrated in FIGS. 9A-9E may be implemented with different dimensions, spacings, and repetitions. The specific features of each pattern (squares, circles, crosses, L-shapes, or spirals) may be scaled or modified to optimize sensitivity for particular alignment requirements. Multiple pattern types may be combined to provide comprehensive alignment verification capabilities. The thermal conductivity characteristics of each pattern may provide distinct signatures that enable precise measurement of overlay errors between bonded structures.

In various embodiments, the overlay targets described in previous figures are specifically designed structures implemented at the bonding interface for the purpose of alignment verification through thermal conductivity measurements. Unlike incidental metal features such as interconnect lines or vias that may exist at bonding interfaces for electrical connections, these overlay targets are purposefully patterned with geometries (illustrated in FIGS. 8A-9E) optimized for alignment detection. In one or more embodiments, the thermal conductivity across the interface reaches maximum when complementary targets are perfectly aligned and decreases predictably with misalignment. This engineered thermal response enables quantitative measurement of alignment errors through non-destructive thermal detection methods. The overlay targets may be implemented in dedicated measurement regions without interfering with functional circuit elements, providing reliable alignment verification capability that is independent of circuit design or interconnect patterns. This targeted approach to alignment measurement provides advantages in sensitivity and reliability compared to attempting alignment measurements using arbitrary metal features that may be present for other purposes.

It is noted that while the schematic drawings show interconnect dimensions that appear to be of the same order as the wavelength of the incoming light (approximately 1000 nm), in some embodiments, the overlay target may have critical dimensions in the 10-100 nm range. At these dimensions, misalignment or overlay error may manifest as a variation in thermal conductivity across an ensemble of interconnects in the device. In one or more embodiments, the thermal measurement approach may detect collective effects of these nanoscale alignment variations rather than attempting to optically resolve individual features. In various embodiments, information about the device design may augment the reference database and subsequent data analysis. This design information, when combined with machine learning and inference techniques, may enhance the system's ability to accurately interpret thermal signatures and correlate them with specific overlay error patterns at nanoscale dimensions.

In addition to the multi-spot/flood imaging approaches, and single-spot/scanning approaches, as well as the bandgap photoluminescence approaches, other embodiments may use different thermal imaging techniques to form the temperature maps used to detect overlay errors in the bonded wafer. For example, other approaches may use a multi-spot approach with multiple illumination spots created using an acousto-optic deflection (AOD) technique. Likewise, temperature measurement techniques are not limited to the bandgap photoluminescence, but may use mid-infrared thermal imaging camera to register black body radiation, particularly when combined with spatial filtering, as well as other suitable temperature measurement techniques.

The above detailed description focuses on D2W (die-to-wafer) and W2W (wafer-to-wafer) applications. For those applications with e.g. silicon substrates one may use near-infra-red light for heating up the sample, for example in 700 nm to 900 nm range, and then collect photoluminescence light also from near-infrared wavelengths, for example in 1000 to 1200 nm range. However, the systems and methods of this disclosure are not limited to bonded wafers, and in the inspection of photomasks or advanced packaging processes on glasses, the same wavelengths may not be suitable, and there is no semiconductor bandgap photoluminescence effect. In contrast, other embodiments may deliver heat to e.g. glass layers by using e.g. short-wave-infra-red or mid-infra-red wavelengths instead of near-infrared, or by heating highly absorbing metal layers directly.

A feature of the method is to select the light of wavelengths that are absorbed in the desired layer of a potential sample (such as a bonded wafer), such as glasses or metals, and then track changes in the temperature of the same or another layer over time using appropriate techniques, not limited to photoluminescence. For example, various embodiments may heat the metal layer with visible light, and then use e.g. black-body radiation detector, such as mid-infra-red camera to measure the temperature of either the metal layer, or another layer, which is thermally connected to the heated layer, and with that thermal connection potentially impacted by overlay targets alignments. Systems capable of implementing the overlay error detection methods described above are illustrated and described using FIGS. 10A-10B below.

Embodiment systems capable of implementing the methods of detecting overlay errors in a bonded wafer described using FIGS. 1, 2, 3, 5A, 6, and 7A are described using FIGS. 10A-10B. FIGS. 10A-10B are schematic diagrams of systems for detecting overlay errors in a bonded wafer 100 in accordance with an embodiment of this disclosure.

FIG. 10A is a schematic diagram of a system 1000a which may be used to implement the methods for detecting overlay errors in the bonded wafer 100 in accordance with embodiments of this disclosure. System 1000a comprises a chamber 1010, a light source 1030, a light detector 1040, a controller 1090, and a memory 1095.

The system 1000a is built around the chamber 1010, which may provide a controlled atmosphere for the analysis process. This chamber 1010 may be capable of maintaining specific environmental conditions such as temperature, pressure, or gas composition to optimize the measurement process. For example, the chamber 1010 may be a vacuum chamber, or a bonding chamber where the bonded wafer 100 was originally bonded. Further, in some embodiments where the chamber is a bonding chamber, the methods of this disclosure may perform the method of detecting overlay errors after an annealing process during the bonding. In other embodiments, the chamber 1010 may be an integrated metrology module.

Within the chamber 1010, a wafer holder 1020 may be positioned to securely support the bonded wafer 100 under examination. The wafer holder 1020 may comprise features for precise positioning and potentially for temperature control of the sample. In various embodiments, the wafer holder may be a conventional wafer holder known in the art, such as an electrostatic chuck, a vacuum chuck, or other forms of chucks that mechanically grip the bonded wafer 100 to hold it in place.

In one or more embodiments, the light source 1030 may be situated outside the chamber 1010, directing illumination through a first window 1035 into the chamber to heat the bonded wafer 100 for the methods of this disclosure. This light source 1030 provides the excitation energy necessary for inducing thermal changes in the bonded wafer 100. Additionally, in embodiments that use bandgap photoluminescence, the light source 1030 may provide the light to cause the stimulated emission of photoluminescence photons.

In some embodiments, the light detector 1040 may be positioned to receive light emitted from the sample through a second window 1045. This detector captures the optical signals that carry information about the thermal properties of the bonded wafer 100, which may be used to determine temperature maps of the bonded wafer 100.

In various embodiments, between the second window 1045 and the light detector 1040, relay optics 1050 may be arranged to collect, focus, and potentially filter the emitted light. These optics may comprise various elements such as lenses, mirrors, or filters to optimize the signal reaching the detector. For example, in an embodiment, the relay optics 1050 comprise a spatial filter to select a specific measurement depth and a specific measurement layer thickness. In various embodiments, the relay optics 1050 may comprise the imaging optics 550 of FIG. 5A.

In certain embodiments, a spot scanning approach may be used where the light source 1030 may illuminate specific spots of the bonded wafer 100, and the light detector 1040 may image specific spots of the bonded wafer 100. For example, in certain embodiments, the relay optics 1050 may comprise mirrors or lenses that individually move for each of the light source 1030 and the light detector 1040. As a result, the mirrors or the lenses used in the relay optics 1050 may enable the imaging and illuminating of different regions of the bonded wafer 100, or the same region of the bonded wafer 100 simultaneously.

In other embodiments, a flood illumination approach may be enabled to image an entire surface of the bonded wafer 100 after flooding the surface with illumination light to heat the bonded wafer 100, or to image particular regions of the bonded wafer 100 after flooding the surface with illumination light.

The system 1000a may be managed by a controller 1090, which coordinates the operations of various components. This controller may adjust parameters such as illumination intensity, detection sensitivity, or sample positioning to optimize the measurement process. Further, the controller 1090 may be electrically coupled to the light source 1030, the light detector 1040, and the wafer holder 1020 to control the system 1000a and implement the method for detecting overlay errors in a bonded wafer of this disclosure.

In various embodiments, a memory 1095 may be connected to the controller 1090, which stores data, measurement parameters, and any potential analysis algorithms used to detect overlay errors in the bonded wafer 100. This memory allows for the recording of measurement results and the implementation of sophisticated data processing techniques. In various embodiments, the memory 1095 may store instructions to be executed in the controller 1090. The instructions when executed may cause the controller to: receive a bonded wafer in a bonding chamber, the bonded wafer comprising a first structure bonded to a second structure at a bonding interface, wherein the first structure comprises first overlay targets aligned with second overlay targets of the second structure at the bonding interface; illuminate a first light beam onto a first portion of the bonded wafer for a first time duration comprising a start time; detect, using a light detector, a first temperature map of a region of the bonded wafer, around the first portion illuminated by the first light beam, the first temperature map being detected after a second time duration; and determine, based on the first temperature map, an overlay error at the bonding interface from misalignment between the first overlay targets and the second overlay targets. In various embodiments, the memory 1095 may further store instructions to be executed in the controller 1090 for the operations as described with reference to FIGS. 1 to 9E.

In various embodiments, the first window 1035 and the second window 1045 may be any material suitable for allowing the illumination light, excitation light, and emitted light to pass through without impeding the light, such as crystalline silicon (c-Si), SiO₂, quartz, glass, Al₂O₃ (sapphire), or other suitable materials. Further, the first window 1035 and the second window 1045 may be any material that enables NIR, SWIR, or any particular wavelength of light suitable for the methods of this disclosure to pass through unimpeded.

The light detector 1040 may be any device known in the art suitable for collecting wavelengths of emitted light from the bonded wafer 100 to measure the temperature. For example, the light detector 1040 may be photodiodes, a photomultiplier tube (PMT), charge-coupled devices (CCDs), complementary metal-oxide-semiconductor (CMOS) sensors, phototransistors, or lasers such as a Q-switched laser. Further, the light detector 1040 may be a single point or a multi-pixel imaging sensor. In some embodiments, the light detector 1040 may be the light detector 160 of FIG. 1, or the light detector 560 of FIG. 5A. In some embodiments, the light detector 1040 may be an infrared camera or a mid-infrared camera. In other embodiments, the light detector 1040 may be a time delay integration (TDI) sensor. In various embodiments, the light detector 1040 may be an imaging microscope capable of flood illumination, where the imaging microscope is either a bandgap photoluminescence microscope or a mid-infrared (mid-IR) camera. And in even further embodiments, the light detector 1040 may be a spot scanning system configured to implement the spot scan approach.

The light source 1030 may be any device known in the art suitable for generating the light used to project the illumination light or excitation light onto the bonded wafer 100 to heat particular layers of the bonded wafer 100 or cause the stimulated emission of photoluminescence photons to be used to measure the temperature of the bonded wafer 100. For example, the light source 1030 may be a pulsed or continuous (CW) laser or laser diode, light emitting diode (LED), a broadband light source, a gas discharge flash lamp, or lasers such as a Q-switched laser. In various embodiments, the light source 1030 may be capable of producing a spectrum of wavelengths of light (λ) between about 700 nm and about 1200 nm (700 nm≤λ≤1200 nm) to compromise between optical resolution and chamber material transmissive properties.

The light source 1030 may be pulsed, or made to emit light over brief timeframes, and then immediately followed by the temperature mapping of the bonded wafer 100 to avoid the heat from the illumination redistributing through the bonded wafer 100 before measuring the temperature map and monitoring rapid changes of temperature. For example, the light source 1030 may emit at frequencies (f) between about 100 Hz to about 10 kHz (100 Hz≤f≤10 kHz). And after measuring a plurality of temperature maps for a second time duration, a waiting period may be implemented to allow the heat to redistribute through the entire bonded wafer 100 to reach thermal equilibrium before the light source 1030 is pulsed again.

In various embodiments, the light source 1030 may be advantageously selected for the optimal heating depending on the type of material of the bonded wafer 100. Various embodiments may use light in the visible spectrum, the ultraviolet spectrum, or the infrared spectrum of wavelengths to illuminate and heat the surface of the bonded wafer 100.

The memory 1095 may be any suitable memory device for storing instructions for performing the method of this disclosure to be executed by the controller 1090. Further, the memory 1095 may be any suitable device capable of storing measurements made by the system 1000a (such as an EPD by a light sensing element of the light detector 1040). For example, the memory 1095 may be a solid state drive (SSD), a hard disk drive (HDD), or some form of volatile memory device such as dynamic random access memory (DRAM).

The controller 1090 may be any suitable device capable of executing the method of this disclosure. By controlling the light source 1030 to emit light to heat the bonded wafer 100, and by controlling the wafer holder 1020 to hold the bonded wafer 100 and collect emitted light using the light detector 1040, the controller 1090 may implement the method for detecting overlay errors in a bonded wafer of this disclosure. In various embodiments, the controller 1090 may be an application specific integrated circuit (ASIC), a field programmable gate array (FPGA), a microcontroller (MCU), or some form of programmable logic circuit (PLC). The controller 1090 in FIG. 10A is capable of implementing the multi-spot approach of illuminating multiple spots over the bonded wafer 100 or the entire bonded wafer 100, and may implement methods for a stationary bonded wafer 100, such as method 1100 described using the flowchart of FIG. 11.

The configuration shown in FIG. 10A represents an integrated approach to thermal analysis of bonded wafer structures. By combining controlled environmental conditions, precise optical excitation and detection, and computerized control and analysis, this system enables detailed, non-destructive evaluation of bonded interfaces and can identify overlay errors that may impact the performance or reliability of bonded wafer structures.

FIG. 10B is a schematic diagram of a system 1000b which may be used to implement the methods for detecting overlay errors in the bonded wafer 100 in accordance with embodiments of this disclosure. System 1000b comprises the chamber 1010, the controller 1090, and the memory 1095. Similarly labeled elements may be as previously described.

In contrast to the system 1000a of FIG. 10A, the light source 1030 and the light detector 1040 are disposed within the chamber 1010 in system 1000b of FIG. 10B. Consequently, the system 1000b does not use windows to optically couple the light source 1030 and the light detector 1040 to the chamber 1010. The chamber 1010 in system 1000b comprises the light source 1030, the light detector 1040, the relay optics 1050, the wafer holder 1020, and a TZ stage 1060. Further, the bonded wafer 100 is disposed on the wafer holder 1020 within the chamber 1010.

FIG. 10B illustrates an alternative configuration of the thermal analysis system, designated as system 1000b. This setup incorporates additional components to enhance the flexibility and enable scanning capabilities for the implementation of single-spot approaches to the method of detecting overlay errors in a bonded wafer of this disclosure. For example, the system 1000b may implement the methods illustrated using FIGS. 1-3 and 7A.

The core of the system 1000b remains the chamber 1010, which provides a controlled environment for the analysis process. Within this chamber, the wafer holder 1020 is positioned to securely support and potentially control the temperature of the bonded wafer 100 under examination. Additionally, the chamber 1010 comprises the light detector 1040 coupled to a second scanner 1080, the light source 1030 coupled to a first scanner 1070, relay optics 1050 (which may be as described for the optics illustrated in FIGS. 1-7A), and the wafer holder 1020 disposed on the TZ stage 1060.

In various embodiments, the first scanner 1070 and the second scanner 1080 enable the scanning of a single-spot across the bonded wafer 100. The first scanner 1070 and second scanner 1080 are optional configurations to enable the scanning. In other embodiments, the first scanner 1070 and second scanner 1080 are not present and the scanning is enabled using the TZ stage 1060 which can move the wafer holder 1020 in translational movements, rotational movements, and longitudinal movements. In some embodiments, the first scanner 1070 and the second scanner 1080 may be the same scanner coupled to both the light source 1030 and the light detector 1040. The light source 1030 may be as described above for system 1000a, and the light detector 1040 may be as described above for system 1000a.

Again, the relay optics 1050 may be positioned to collect, focus, and potentially filter the emitted light. And the relay optics 1050 may optimize the signal quality reaching the light detector 1040. In various embodiments, an additional spatial filter may be added to control stray light, or potential ambient light.

The main difference between system 1000b and the system 1000a is the enablement of potential scanning embodiments in the system 1000b. Specifically, the scanning may be enabled by the first scanner 1070, the second scanner 1080, and/or the TZ stage 1060.

The TZ stage 1060 may be configured to perform movements of the bonded wafer 100 in X, Y, and Z linear directions, as well as perform rotations about a rotation direction, T. Specifically, the TZ stage 1060 may be configured to perform vertical and rotational movements, such as moving the bonded wafer 100 up or down in the Z direction, and a linear stage of the TZ stage 1060 may be configured to perform translational movements within the XY plane. Various conventional stages may be used for the TZ stage 1060 where a stage controller (not shown) may control drivers of the stage to perform the scanning.

In the embodiment illustrated in FIG. 10B, the controller 1090 may be coupled to the wafer holder 1020, the TZ stage 1060, the first scanner 1070, the second scanner 1080, the light source 1030, the light detector 1040, and the second scanner 1080. Additionally, in the system 1000b, the controller 1090 may be coupled to the memory 1095 storing instructions to be executed in the controller 1090. The controller 1090, and the memory 1095 may be as described above.

The system 1000b configuration, with its scanning capability, provides enhanced spatial resolution and flexibility in thermal analysis of bonded wafer structures. This setup allows for rapid, high-resolution mapping of thermal properties across the wafer surface, enabling detailed detection and characterization of misalignment between overlay targets in bonded interfaces. The integration of scanning capabilities with precise optical components and computerized control allows for advanced non-destructive evaluation techniques to be applied to bonded wafer structures. Additional example embodiment methods for detecting overlay errors which may be implemented using either of the systems 1000a-b of FIGS. 10A-10B are described using the flowcharts of FIGS. 11-12.

In various embodiments, the systems 1000a-b may be integrated into high-volume manufacturing environments where throughput requirements may reach 20,000 dies per wafer per hour. The integration may be achieved through automated wafer handling systems that connect measurement chambers with other processing chambers in the manufacturing line. Load-lock chambers may enable efficient wafer transfer while maintaining controlled environmental conditions, and robotic transfer systems may move wafers between chambers and measurement stages.

In one or more embodiments, the system may be configured either as a standalone metrology unit or as an integrated inline measurement station. The measurement chamber connects to factory automation systems through standardized interfaces, with a control system coordinating wafer movement, measurement sequences, and data collection. This configuration enables rapid, automated overlay error detection without breaking the production flow. In various embodiments, the thermal relaxation times in bonded structures may range from milliseconds to microseconds. Rapid measurement capability of the systems 1000a-b, combined with automated handling and environmental controls, ensures reliable measurements while maintaining the high throughput required for volume manufacturing.

FIG. 11 illustrates a method 1100 for overlay error detection through temperature mapping, in accordance with an embodiment. At operation 1110, a bonded wafer is received in a bonding chamber, where the bonded wafer may be the bonded wafer 100 as previously described. The bonded wafer may comprise the first structure 10 bonded to the second structure 20 through the bonding layer containing overlay targets. The bonding layer may include the first and the second bonding layers 112 and 114, with the first overlay targets 110 aligned with the second overlay targets 116 at the bonding interface 113 as described with reference to FIG. 1.

At operation 1120, a first light beam (e.g., the light beam 102) may illuminate a first portion of the bonded wafer for a first time duration (e.g., the first time duration 401) starting at a start time. Regions around the first portion may be illuminated, the regions may include the region 120 in a single-spot configuration, or one of multiple regions 120a-f in a multi-spot configuration as described in previous figures.

In operation 1130, a light detector (such as detector 160 in single-spot configuration, detector 560 in multi-spot configuration, or detector 760 in rotating configuration) may detect a first temperature map of the region around the illuminated portion. The temperature map may be detected after the start time for a second time duration (e.g., the second time duration 402), using configurations of optical elements and spatial filters as previously described in relation to FIGS. 1-7A.

Finally, at operation 1140, the method determines an overlay error at the bonding interface 113 based on the detected temperature map. The overlay error indicates misalignment between the first overlay targets 110 and second overlay targets 116, which may be arranged in various patterns as illustrated in FIGS. 8A-9E to optimize thermal conductivity contrast for alignment measurement.

FIG. 12 illustrates a method 1200 for developing a database and determining overlay error of bonded wafers based on the database, in accordance with an embodiment. At operation 1210, overlay metrology techniques such as scanning electron microscopy (SEM), transmission electron microscopy (TEM), or X-ray diffraction measurements may determine overlay errors in a calibration bonded wafer. These high-precision measurements establish accurate reference values for known overlay errors in the calibration wafer. The calibration bonded wafer may comprise a first structure bonded to a second structure as described with reference to FIG. 1.

At operation 1220, a first light beam (e.g. the light beam 102) may illuminate the calibration bonded wafer to obtain calibrated temperature maps. In various embodiments, obtain calibrated temperature maps may involve collecting comprehensive thermal response data including temperature versus time profiles, spatial temperature distributions, and temporal evolution of thermal patterns. Multiple calibration wafers with different measured overlay errors may be measured to build a robust dataset covering various misalignment scenarios between overlay targets.

In various embodiments, machine learning and artificial intelligence (AI) techniques may be applied to analyze the collected calibration data. The analysis may employ neural networks trained to recognize patterns in temperature maps corresponding to specific overlay errors. These networks may develop predictive models that correlate temporal thermal responses with alignment accuracy. Pattern recognition algorithms may identify characteristic thermal signatures while regression models relate temperature gradients to quantitative overlay measurements. The AI-based analysis may establish statistical correlations between thermal features and alignment parameters, creating a comprehensive framework for interpreting thermal measurement data.

At operation 1230, a bonded test wafer (e.g., the bonded wafer 100) may be received for overlay error measurement. The bonded test wafer may comprise a first test structure bonded to a second test structure, similar to the previously described the first structure 10 bonded to the second structure 20, with corresponding overlay targets 110 and 116 at the bonding interface 113.

In operation 1240, a second light beam (e.g., the light beam 120) may illuminate the bonded test wafer to obtain its temperature map. The illumination and detection may employ similar configurations as used for the calibration measurements, maintaining consistent measurement conditions between calibration and test measurements.

Finally, at operation 1250, the trained machine learning models and established database may be used to determine overlay errors in the bonded test wafer. The AI-based analysis may compare measured thermal responses with calibrated references to provide rapid and quantitative overlay error measurements without requiring expensive inspection methods. In various embodiments, the database may incorporate device design information to enhance the analysis of thermal signatures from nanoscale overlay targets. This device design information may enable the system to account for the collective thermal behavior of ensembles of interconnects with critical dimensions in the 10-100 nm range, improving measurement accuracy and reliability when detecting overlay errors at these scales.

While FIGS. 11 and 12 illustrate the fundamental process flows for overlay error detection, these methods may incorporate any of the structural elements, components, and operational variations described in previous figures. For example, the illumination step may employ any of the beam configurations shown in FIGS. 1-7B, including single-spot or multi-spot illumination, various optical filtering arrangements, or different scanning approaches. The light beam may be operated in pulsed or continuous modes as detailed in FIGS. 4A-4D. The bonded wafer may incorporate any of the overlay target patterns illustrated in FIGS. 8A-9E at the bonding interface. The detection system may utilize various optical configurations, filtering schemes, and detector arrangements as shown in FIGS. 3-7b, and may implement different scanning methods including wafer rotation or detector movement. The measurement chamber may be configured as standalone equipment or integrated into manufacturing lines as described in FIGS. 10A-10B. These various embodiments and their combinations provide flexibility in implementing the basic process steps while maintaining the fundamental approach of thermal-based overlay error detection.

Example embodiments of the invention are described below. Other embodiments can also be understood from the entirety of the specification as well as the claims filed herein.

Example 1. A method for overlay error detection in a bonded wafer, the method including: receiving a bonded wafer in a bonding chamber, the bonded wafer including a first structure bonded to a second structure at a bonding interface, where the first structure includes first overlay targets aligned with second overlay targets of the second structure at the bonding interface; illuminating a first light beam onto a first portion of the bonded wafer for a first time duration including a start time; detecting, using a light detector, a first temperature map of a region of the bonded wafer around the first portion illuminated by the first light beam, the first temperature map being detected after the start time for a second time duration; and determining, based on the first temperature map, an overlay error at the bonding interface from misalignment between the first overlay targets and the second overlay targets.

Example 2. The method of example 1, where detecting the first temperature map includes: illuminating the bonded wafer to cause the bonded wafer to emit bandgap photoluminescence light; collecting the bandgap photoluminescence light using the light detector; and determining, based on the bandgap photoluminescence light, temperatures to construct the first temperature map of the bonded wafer.

Example 3. The method of one of examples 1 or 2, where detecting the first temperature map includes: illuminating the bonded wafer to cause the bonded wafer to emit blackbody radiation; filtering the blackbody radiation using a spatial filter; collecting the blackbody radiation using the light detector; and determining, based on the blackbody radiation, temperatures to construct the first temperature map of the bonded wafer.

Example 4. The method of one of examples 1 to 3, further including rotating the bonded wafer while illuminating the first light beam.

Example 5. The method of one of examples 1 to 4, where illuminating the first light beam includes: generating a series of beam pulses at a predetermined frequency during the first time duration; and synchronizing the light detector to activate and deactivate in accordance with the predetermined frequency to detect the first temperature map of the bonded wafer.

Example 6. The method of one of examples 1 to 5, where illuminating the first light beam includes: generating a series of beam pulses at a predetermined frequency during the first time duration; and maintaining the light detector in a continuously activated state to detect the first temperature map of the bonded wafer during both beam pulse periods and intervals between beam pulses.

Example 7. The method of one of examples 1 to 6, where: the first overlay targets include a first set of geometrical patterns; and the second overlay targets include a second set of geometrical patterns configured to align with the first set of geometrical patterns at the bonding interface.

Example 8. The method of one of examples 1 to 7, where the first set of geometrical patterns include rectangle, square, cross, L-shape, circle, or spiral-shaped pattern.

Example 9. The method of one of examples 1 to 8, further including: illuminating a second light beam onto a second portion of the bonded wafer for the first time duration; detecting, using the light detector, a second temperature map of the bonded wafer, the second temperature map being detected after the second time duration; and determining, based on the second temperature map, the overlay error at the bonding interface from misalignment between the first overlay targets and the second overlay targets.

Example 10. The method of one of examples 1 to 9, where detecting the first temperature map includes measuring a plurality of temperatures at different times during the second time duration.

Example 11. A method for overlay error detection, the method including: determining an overlay error for a calibration bonded wafer including a first structure bonded to a second structure; illuminating a first light beam onto the calibration bonded wafer and imaging a temperature response to the first light beam to obtain a calibrated temperature map; receiving a bonded test wafer including a first test structure bonded to a second test structure; illuminating a second light beam onto the bonded test wafer and imaging a temperature response of the bonded test wafer to the second light beam to obtain a temperature map; and determining an overlay error of the bonded test wafer based on the temperature map of the bonded test wafer and the calibrated temperature map.

Example 12. The method of example 11, where determining the overlay error includes generating a model based on the calibrated temperature map and determining the overlay error using the model.

Example 13. The method of one of examples 11 or 12, where determining the overlay error includes generating a database based on the calibrated temperature map and determining the overlay error using the database. 14. The method of one of examples 11 or 12, where generating the database includes: generating temperature versus time profiles for the calibration wafer; and correlating temporal changes in the temperature versus time profiles with corresponding overlay errors.

Example 15. The method of one of examples 11 to 14, where obtain the temperature map includes measuring a plurality of temperatures at different times during a time duration.

Example 16. A system for overlay error detection, the system including: a wafer holder disposed in a chamber; a light source and a light detector; and a controller coupled to the wafer holder, the light source and the light detector, and a memory storing instructions to be executed in the controller, the instructions when executed cause the controller to: receive a bonded wafer in a bonding chamber, the bonded wafer including a first structure bonded to a second structure at a bonding interface, where the first structure includes first overlay targets aligned with second overlay targets of the second structure at the bonding interface, illuminate a first light beam onto a first portion of the bonded wafer for a first time duration including a start time, detect, using a light detector, a first temperature map of a region of the bonded wafer, around the first portion illuminated by the first light beam, the first temperature map being detected after a second time duration, and determine, based on the first temperature map, an overlay error at the bonding interface from misalignment between the first overlay targets and the second overlay targets.

Example 17. The system of example 16, where the light source includes a laser diode, or a pulsed laser.

Example 18. The system of one of examples 16 or 17, where the light detector includes an imaging microscope capable of flood illumination, and where the imaging microscope includes either a bandgap photoluminescence microscope or a mid-infrared camera.

Example 19. The system of one of examples 16 to 18, where the first overlay targets include geometrical pattern of rectangle, square, cross, L-shape, circle, or spiral-shape.

Example 20. The system of one of examples 16 to 19, further including relay optics disposed between the bonded wafer and the light detector to route emitted light from the bonded wafer to the light detector, and where the relay optics include a spatial filter configured to select a measurement depth and a measurement layer thickness of the bonded wafer.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1-12 may be combined in further embodiments. It is therefore intended that the appended claims encompass any such modifications or embodiments.

What is claimed is:

1. A method for overlay error detection in a bonded wafer, the method comprising:
receiving a bonded wafer in a bonding chamber, the bonded wafer comprising a first structure bonded to a second structure at a bonding interface, wherein the first structure comprises first overlay targets aligned with second overlay targets of the second structure at the bonding interface;
illuminating a first light beam onto a first portion of the bonded wafer for a first time duration comprising a start time;
detecting, using a light detector, a first temperature map of a region of the bonded wafer around the first portion illuminated by the first light beam, the first temperature map being detected after the start time for a second time duration; and
determining, based on the first temperature map, an overlay error at the bonding interface from misalignment between the first overlay targets and the second overlay targets.

2. The method of claim 1, wherein detecting the first temperature map comprises:
illuminating the bonded wafer to cause the bonded wafer to emit bandgap photoluminescence light;
collecting the bandgap photoluminescence light using the light detector; and
determining, based on the bandgap photoluminescence light, temperatures to construct the first temperature map of the bonded wafer.

3. The method of claim 1, wherein detecting the first temperature map comprises:
illuminating the bonded wafer to cause the bonded wafer to emit blackbody radiation;
filtering the blackbody radiation using a spatial filter;
collecting the blackbody radiation using the light detector; and
determining, based on the blackbody radiation, temperatures to construct the first temperature map of the bonded wafer.

4. The method of claim 1, further comprising rotating the bonded wafer while illuminating the first light beam.

5. The method of claim 1, wherein illuminating the first light beam comprises:
generating a series of beam pulses at a predetermined frequency during the first time duration; and
synchronizing the light detector to activate and deactivate in accordance with the predetermined frequency to detect the first temperature map of the bonded wafer.

6. The method of claim 1, wherein illuminating the first light beam comprises:
generating a series of beam pulses at a predetermined frequency during the first time duration; and
maintaining the light detector in a continuously activated state to detect the first temperature map of the bonded wafer during both beam pulse periods and intervals between beam pulses.

7. The method of claim 1, wherein:
the first overlay targets comprise a first set of geometrical patterns; and
the second overlay targets comprise a second set of geometrical patterns configured to align with the first set of geometrical patterns at the bonding interface.

8. The method of claim 7, wherein the first set of geometrical patterns comprise rectangle, square, cross, L-shape, circle, or spiral-shaped pattern.

9. The method of claim 1, further comprising:
illuminating a second light beam onto a second portion of the bonded wafer for the first time duration;
detecting, using the light detector, a second temperature map of the bonded wafer, the second temperature map being detected after the second time duration; and
determining, based on the second temperature map, the overlay error at the bonding interface from misalignment between the first overlay targets and the second overlay targets.

10. The method of claim 1, wherein detecting the first temperature map comprises measuring a plurality of temperatures at different times during the second time duration.

11. A method for overlay error detection, the method comprising:
determining an overlay error for a calibration bonded wafer comprising a first structure bonded to a second structure;
illuminating a first light beam onto the calibration bonded wafer and imaging a temperature response to the first light beam to obtain a calibrated temperature map;
receiving a bonded test wafer comprising a first test structure bonded to a second test structure;
illuminating a second light beam onto the bonded test wafer and imaging a temperature response of the bonded test wafer to the second light beam to obtain a temperature map; and
determining an overlay error of the bonded test wafer based on the temperature map of the bonded test wafer and the calibrated temperature map.

12. The method of claim 11, wherein determining the overlay error comprises generating a model based on the calibrated temperature map and determining the overlay error using the model.

13. The method of claim 11, wherein determining the overlay error comprises generating a database based on the calibrated temperature map and determining the overlay error using the database.

14. The method of claim 13, wherein generating the database comprises:
generating temperature versus time profiles for the calibration wafer; and
correlating temporal changes in the temperature versus time profiles with corresponding overlay errors.

15. The method of claim 11, wherein obtain the temperature map comprises measuring a plurality of temperatures at different times during a time duration.

16. A system for overlay error detection, the system comprising:
a wafer holder disposed in a chamber;
a light source and a light detector; and
a controller coupled to the wafer holder, the light source and the light detector, and a memory storing instructions to be executed in the controller, the instructions when executed cause the controller to:
receive a bonded wafer in a bonding chamber, the bonded wafer comprising a first structure bonded to a second structure at a bonding interface, wherein the first structure comprises first overlay targets aligned with second overlay targets of the second structure at the bonding interface,
illuminate a first light beam onto a first portion of the bonded wafer for a first time duration comprising a start time,
detect, using a light detector, a first temperature map of a region of the bonded wafer, around the first portion illuminated by the first light beam, the first temperature map being detected after a second time duration, and
determine, based on the first temperature map, an overlay error at the bonding interface from misalignment between the first overlay targets and the second overlay targets.

17. The system of claim 16, wherein the light source comprises a laser diode, or a pulsed laser.

18. The system of claim 16, wherein the light detector comprises an imaging microscope capable of flood illumination, and wherein the imaging microscope comprises either a bandgap photoluminescence microscope or a mid-infrared camera.

19. The system of claim 16, wherein the first overlay targets comprise geometrical pattern of rectangle, square, cross, L-shape, circle, or spiral-shape.

20. The system of claim 16, further comprising relay optics disposed between the bonded wafer and the light detector to route emitted light from the bonded wafer to the light detector, and wherein the relay optics comprise a spatial filter configured to select a measurement depth and a measurement layer thickness of the bonded wafer.
